(19) United States
(12) Patent Application Publication
(10) Pub. No.: US 2025/0329607 A1
(43) Pub. Date: Oct. 23, 2025

(54) OPTICAL MODULE INCLUDING HEAT DISSIPATION COMPONENT IN CONTACT WITH ELECTRONIC COMPONENT

(71) Applicant: Prime World International Holdings Ltd., New Taipei City (TW)

(72) Inventors: Che-Shou YEH, New Taipei City (TW); Ming-You LAI, New Taipei City (TW); Hsuan-Chen SHIU, New Taipei City (TW); Yu CHEN, New Taipei City (TW); Yi-Ju WANG, New Taipei City (TW); Ling-An KUNG, New Taipei City (TW)

(21) Appl. No.: 18/751,979

(22) Filed: Jun. 24, 2024

(30) Foreign Application Priority Data
Apr. 22, 2024 (TW) 113114849

(51) Int. Cl. H01L 23/427; G02B 6/42; H01L 25/16

(52) U.S. Cl. CPC H01L 23/427; G02B 6/4268; H01L 25/167

(57) ABSTRACT

The present disclosure provides an optical module, comprising a substrate, an electronic component, and a heat dissipation component. The electronic component is disposed on the substrate. The heat dissipation component is in thermal contact with the electronic component. The heat dissipation component includes a heat dissipation body and a thermally conductive medium. The heat dissipation body is located between the electronic component and the thermally conductive medium. The electronic component has a mounting surface and a heat dissipation surface opposite to each other. The mounting surface faces toward the substrate. The heat dissipation body is in contact with the heat dissipation surface.

### CROSS-REFERENCE TO RELATED APPLICATIONS

This non-provisional application claims priority under 35 U.S.C. § 119 (a) on Patent Application No(s). 113114849 filed in Taiwan, ROC on Apr. 22, 2024, the entire contents of which are hereby incorporated by reference.

### BACKGROUND

### Technical Field

The present disclosure relates to an optical module with a heat dissipation component.

### Related Art

Optical modules can transmit and/or receive optical signals for various applications including, but not limited to, internet data center, Cable TV, and fiber to the home (FTTH). Using optical modules for transmission can provide higher transmission rates and signal bandwidth over longer transmission distances. In order to enhance the compatibility of optical internetworking products all over the world and to reduce the burden of maintenance, organizations such as Multi-Source Agreement (MSA), Institute of Electrical and Electronic Engineers (IEEE), and Optical Internetworking Forum (OIF) have developed several form factors adapted to different signal transmission rates. These form factors include, but not limited to, XFP, SFP, QSFP (Quad Small Form Factor Pluggable), QSFP-DD (Double Density), OSFP (Octal Small Form Factor Pluggable), and CPO (Co-Packaged Optics).

However, conventional optical modules still present some problems, such as optical efficiency (power), space management, thermal management, insertion loss and manufacturing yield.

### SUMMARY

According to one embodiment of the present disclosure, an optical module includes a substrate, an electronic component, and a heat dissipation component. The electronic component is disposed on the substrate. The heat dissipation component is in thermal contact with the electronic component. The heat dissipation component includes a heat dissipation body and a thermally conductive medium. The heat dissipation body is located between the electronic component and the thermally conductive medium. The electronic component has a mounting surface and a heat dissipation surface opposite to each other. The mounting surface faces toward the substrate. The heat dissipation body is in contact with the heat dissipation surface.

According to another embodiment of the present disclosure, a receiver optical subassembly includes a photodiode, a substrate, a transimpedance amplifier, and a heat dissipation component. The transimpedance amplifier is disposed on the substrate and electrically connected to the photodiode. The heat dissipation component is in thermal contact with the transimpedance amplifier. The transimpedance amplifier has a flip chip structure. The transimpedance amplifier has a mounting surface and a heat dissipation surface opposite to each other. The mounting surface faces toward a substrate. The heat dissipation component is in contact with the heat dissipation surface.

According to still another embodiment of the present disclosure, an optical module includes an optical communication unit, an electronic component, a heat dissipation component, and a protective cover. The electronic component is electrically connected to the optical communication unit. The heat dissipation component includes a heat dissipation body and a thermally conductive medium. The heat dissipation body is located between the electronic component and the thermally conductive medium. The heat dissipation body is in thermal contact with the electronic component. The protective cover has an opening. The heat dissipation body extends through an opening. An entirety of the thermally conductive medium and the electronic component are located on opposite sides of the protective cover, respectively.

### BRIEF DESCRIPTION OF THE DRAWINGS

The present disclosure will become better understood from the detailed description given hereinbelow and the accompanying drawings which are given by way of illustration only and thus are not intended to limit the present disclosure and wherein:

FIG. 1 is a block diagram of an optical module according to an embodiment of the present disclosure;

FIG. 2 is a block diagram of an optical module according to another embodiment of the present disclosure;

FIG. 3 is a schematic view of components of an optical module according to an embodiment of the present disclosure;

FIG. 4 is a side view of the components in FIG. 3;

FIG. 5 is a partially enlarged view of the components in FIG. 4;

FIG. 6 is a side view of components of an optical module according to another embodiment of the present disclosure; and

FIG. 7 is a side view of components of an optical module according to still another embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

The thermal management of an optical module mainly relates to transferring the heat generated by components to a housing to dissipate the heat to the outside, so that each component is able to operate within an appropriate temperature range. Therefore, the heat is required to be effectively transferred inside the optical module, thereby optimizing the performance and the reliability of signal transmission. The internal design of the optical module has a significant impact on heat dissipation efficiency. Currently, heat dissipation components, such as heat sinks or metal blocks, are configured to enhance the heat dissipation efficiency. However, as to an optical module with high transmission rate and compact configuration, the degradation of heat dissipation efficiency is one of the problems found by inventors. For example, the heat dissipation component is too far away from the heat source to effectively dissipate a large amount of heat. On the other hand, when the internal temperature of the optical module becomes high, the heat dissipation component may release a liquid to facilitate heat dissipation, but the liquid may contaminate the interior of the optical module, thereby adversely affecting the performance of signal transmission.

According to one embodiment of the present disclosure, the protective cover and the flange of the heat dissipation component prevent the heat conducting constituent of the thermally conductive medium from flowing to the electronic component or the substrate. The protective cover is able to block the liquid heat conducting constituent, such that the heat conducting constituent may be accumulated above the protective cover. Alternatively, in order to facilitate the assembly, there may be a gap between the heat dissipation body and the opening, and the liquid heat conducting constituent may flow under the protective cover via the gap. In this case, the flange is able to allow the liquid heat conducting constituent flowing under the protective cover to be located in a space between the flange and the protective cover and supported by the flange, thereby preventing the liquid heat conducting constituent from contaminating the internal environment of the optical module.

According to one embodiment of the present disclosure, an electronic component may have a flip chip structure. Further, a mounting surface of the electronic component may have an electrical interconnect electrically connected to a substrate, and the electrical interconnect may be understood as a metal protrusion, a metal pad, or a pin. A heat dissipation surface of the electronic component may not have electrical interconnect, or may have electrical interconnect while its area is large enough to prevent a heat dissipation body of the heat dissipation component from being in physical contact with the electrical interconnect located on the heat dissipation surface. Therefore, the heat generated by the heat source may be transferred to the heat dissipation component in contact with the heat source without being transferred to the copper pour inside the substrate, thereby improving the heat dissipation efficiency.

Some or all of the technical features disclosed in one or more embodiments of the present disclosure may be combined to achieve corresponding effects.

The term “couple” or “coupled to” refers to any connection, link, or the like. Moreover, the term “optically couple” or “optically coupled to” refers to a relationship where light is transmitted (imparted) from a device to another. Unless otherwise specified, devices that “couple” or “coupled to” each other do not need to be directly connected to each other and may be separated by intervening objects.

The term substantially, as generally referred to herein, refers to a degree of precision within acceptable tolerance that accounts for and reflects minor real-world variation due to material composition, material defects, and/or limitations/peculiarities in manufacturing processes. Such variation may therefore be said to achieve largely, but not necessarily wholly, the stated characteristic.

As used herein, “channel wavelengths” refer to the wavelengths associated with optical channels and may include a specified wavelength band around a center wavelength. More specifically, the channel wavelengths may be defined by an International Telecommunication (ITU) standard such as the ITU-T dense wavelength division in multiplexing (DWDM) grid or coarse wavelength division multiplexing (CWDM). In one embodiment, the channel wavelengths are implemented in accordance with local area network (LAN) wavelength division multiplexing (WDM), which may also be referred to as LWDM.

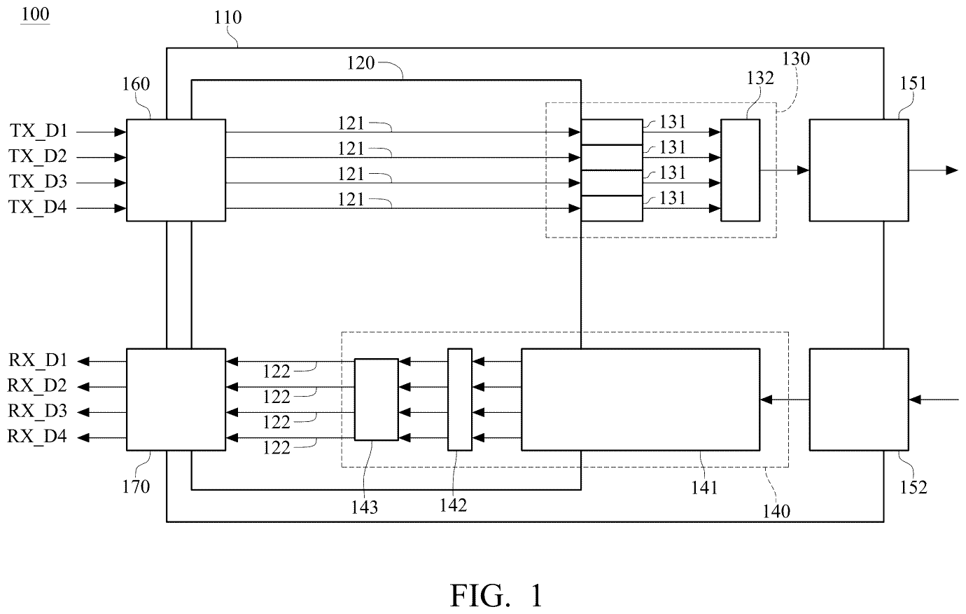

Please refer to FIG. 1. FIG. 1 is a block diagram of an optical module 100 according to an embodiment of the present disclosure. The optical module 100 may include a plurality of components disposed in the housing 110. Further, the optical module 100 may be understood as an optical transceiver or an optical subassembly, and the housing 110 may be understood as an hermetic housing or a non-hermetic housing. FIG. 1 exemplarily illustrates the optical module 100 that is an optical transceiver and may include a substrate 120 disposed in the housing 110. In addition, the optical module 100 may further include a transmitter optical subassembly (TOSA) 130 and a receiver optical subassembly (ROSA) 140 coupled to the substrate 120. In other embodiments where the optical module 100 is an optical subassembly, the optical module 100 may include one of the receiver optical subassembly and the transmitter optical subassembly.

The substrate 120 may be understood as a printed circuit board assembly (PCBA). One end of the substrate 120 may extend from the housing 110 to the outside, to realize the electrical interconnect between the optical module 100 and external circuits. The transmitter optical subassembly 130 and the receiver optical subassembly 140 may be configured to transmit and receive signals of multiple channel wavelengths, respectively. Specifically, the transmitter optical subassembly 130 may transmit optical signals of four different channel wavelengths, and the receiver optical subassembly 140 may receive optical signals of four different channel wavelengths (λ1, λ2, λ3, λ4).

The transmitter optical subassembly 130 may include an optical transferring unit 131 and a multiplexing unit 132. The optical transferring unit 131 may be understood as one or more laser diode(s). The multiplexing unit 132 may include an arrayed waveguide grating (AWG) or any component that is adapted to output multiple channel wavelengths after combining the same. The multiplexing unit 132 may be optically coupled to the optical transferring unit 131 to receive the optical signals transmitted by the optical transferring unit 131. The multiplexing unit 132 may further be optically coupled to the optical fiber connector 151. The optical fiber connector 151 may be understood as a LC connector. The transmitter optical subassembly 130 may further include one or more passive optical components and/or one or more active optical components, such as but not limited to optical isolator, optical modulator, focusing lens, and monitor photodiode.

The receiver optical subassembly 140 may include a demultiplexing unit 141, an optical receiving unit 142, and an amplifier 143. The demultiplexing unit 141 may be understood as an arrayed waveguide grating, the optical receiving unit 142 may be understood as one or more photodiode(s), and the amplifier 143 may be understood as a transimpedance amplifier (TIA). The demultiplexing unit 141 may be optically coupled to the optical fiber connector 152. The optical fiber connector 152 may be understood as a LC connector. The demultiplexing unit 141 may be configured to divide the optical signals into multiple channel wavelengths and output the same to the optical receiving unit 142.

The optical module 100 may further include a transmit connecting circuit 160 (also called TX circuit) electrically connected to the transmitter optical subassembly 130 and a receiver connecting circuit 170 (also called RX circuit) electrically connected to the receiver optical subassembly 140. The transmit connecting circuit 160 may drive the optical transferring unit 131 of the transmitter optical subassembly 130. Further, the substrate 120 may have conductive wires 121 that electrically connect the transmit connecting circuit 160 and the optical transferring unit 131. The transmit connecting circuit 160 may receive driving signals (driving signals TX_D1 to TX_D4 as shown in FIG. 1) from the external circuits. The optical transferring unit 131 may transmit optical signals of certain channel wavelengths according to the driving signals. In addition, the substrate 120 may further have conductive wires 122 that electrically connect the receiver connecting circuit 170 and the amplifier 143. The optical receiving unit 142 may convert the optical signals into electrical signals, and output the electrical signals to the amplifier 143, so that the electrical signals may be amplified and/or modulated. Then, the electrical signals may output the electrical signals RX_D1 to RX_D4 as shown in FIG. 1 through the receiver connecting circuit 170.

In some embodiments, the transmitter optical subassembly 130 or the receiver optical subassembly 140 may be encapsulated in an airtight manner. In this embodiment, the transmit connecting circuit 160 or the receiver connecting circuit 170 may be understood as an electrical feedthrough. More specifically, the transmit connecting circuit 160 or the receiver connecting circuit 170 may be understood as a ceramic circuit board or a flexible circuit board.

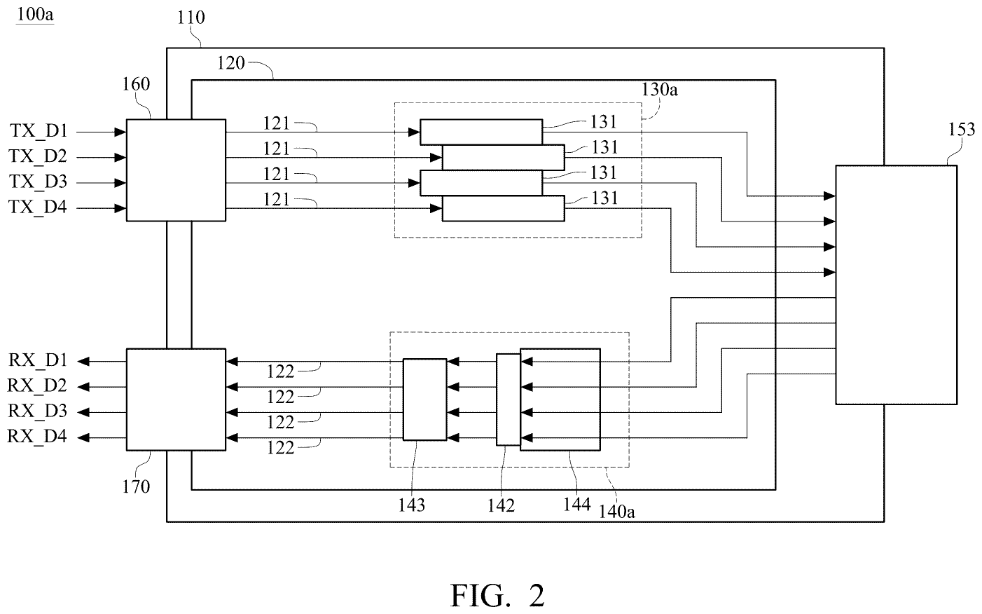

FIG. 2 is a block diagram of an optical module 100a according to another embodiment of the present disclosure. The optical module 100a and the optical module 100 may have similar configurations. The difference between the optical module 100a and the optical module 100 is in that the optical module 100a may include a transmitter optical subassembly 130a without the multiplexing unit and a receiver optical subassembly 140a without the demultiplexing unit. Both of the transmitter optical subassembly 130a and the receiver optical subassembly 140a may be optically coupled to the optical fiber connector 153. The optical fiber connector 153 may be understood as a multi-fiber push on (MPO) connector or an active optical cable (AOC). In addition, the receiver optical subassembly 140a may include an optical fiber array 144 optically coupled to the optical fiber connector 153. The optical receiving unit 142 of the receiver optical subassembly 140a may receive optical signals through the optical fiber array 144.

FIGS. 1 and 2 exemplarily illustrate that the optical module transmits and receives the optical signals of four different channel wavelengths through the transmitter optical subassembly and the receiver optical subassembly, respectively, thereby realizing a signal transmission rate of, for example, 400G bps or higher. However, the number of the channel and the signal transmission rate are not intended to limit the present disclosure.

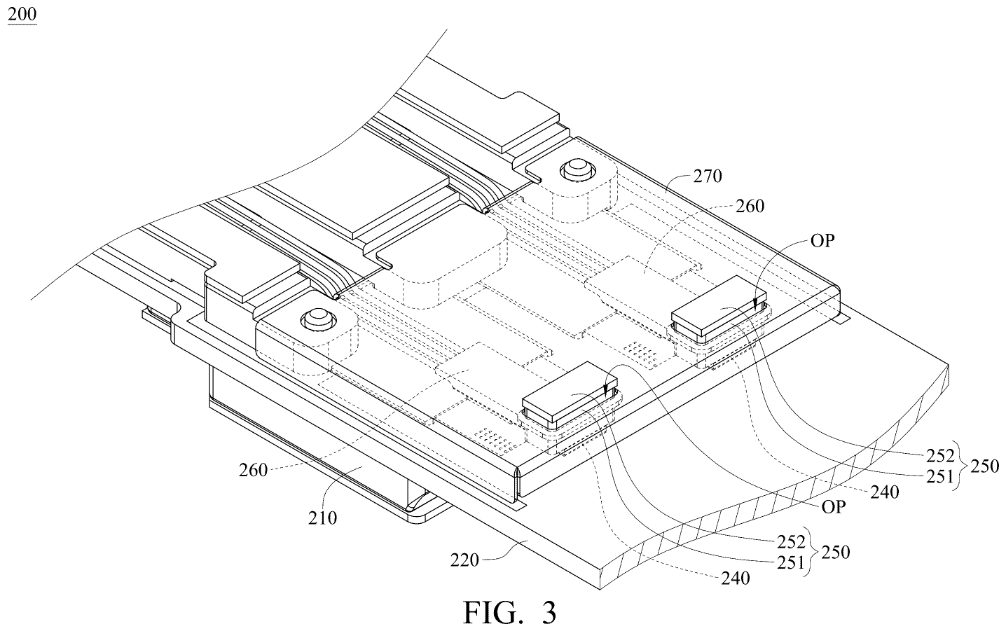

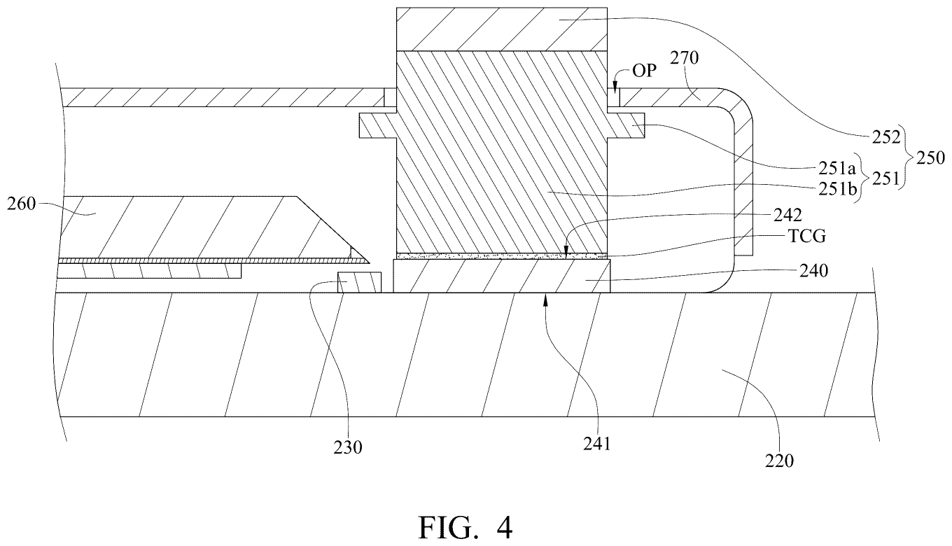

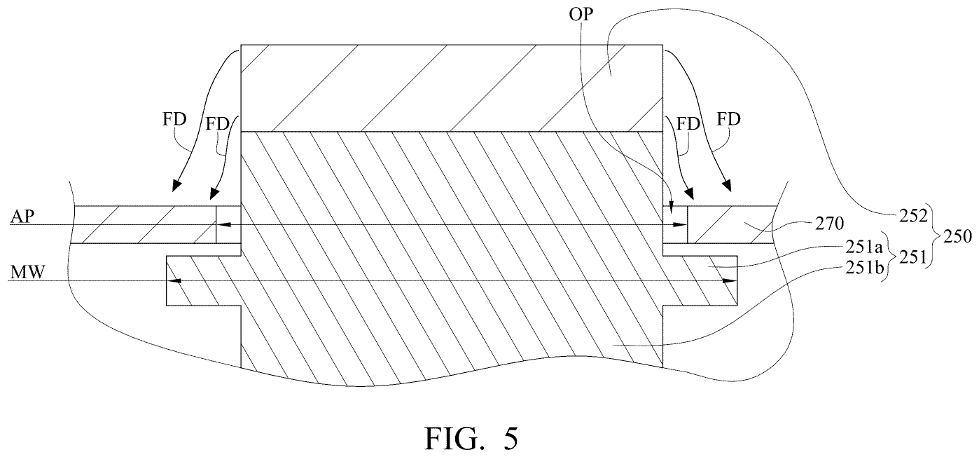

The optical module disclosed in the present disclosure may include a heat dissipation component. Please refer to FIGS. 3 to 5. FIG. 3 is a schematic view of components of an optical module 200 according to an embodiment of the present disclosure, FIG. 4 is a side view of the components in FIG. 3, and FIG. 5 is a partially enlarged view of the components in FIG. 4. In this embodiment, the optical module 200 may include a housing 210, a substrate 220, an optical communication unit 230, an electronic component 240, and a heat dissipation component 250.

The housing 210 may be a housing integrally formed as a single piece, or the housing 210 may include multiple parts such as an upper housing part and a lower housing part. The substrate 220 may be accommodated in the housing 210. The substrate 220 may be a PCBA or a submount for supporting the optical communication unit 230. Further, the substrate 220 may be understood as the substrate 120 shown in FIGS. 1 and 2, may be understood as a submount included in a transmitter optical subassembly 130 or 130a, or may be understood as a submount included in a receiver optical subassembly 140 or 140a.

In one embodiment, the housing 210 may be understood as a transceiver housing. In one embodiment, the housing 210 may be a box for a TOSA module or a ROSA module in the transceiver housing. In one embodiment, the housing 210 may be a carrier coupled to a PCBA and configured to support one or more optical components such as lasers, photodiodes, optical multiplexer, optical demultiplexer or fiber array.

The optical communication unit 230 and the electronic component 240 may be disposed on the substrate 220, the optical communication unit 230 may be configured to transmit or receive optical signals, and the electronic component 240 may be electrically connected to the optical communication unit 230. In this embodiment, the optical module 200 may include a receiver optical subassembly, and the optical communication unit 230 may receive optical signals. In this case, the optical communication unit 230 may be understood as a photodiode, and the electronic component 240 may be understood as a transimpedance amplifier, a clock and data recovery (CDR) chip, or a digital signal processor (DSP). In other embodiments, the optical module 200 may include a transmitter optical subassembly, and the optical communication unit 230 may transmit optical signals. In this case, the optical communication unit 230 may be understood as a laser diode, and the electronic component 240 may be understood as a laser diode driver (LDD), a CDR chip, or a DSP. In addition, the optical module 200 may further include an optical transferring unit 260 that optically connected to the optical communication unit 230. For example, the optical transferring unit 260 is, but not limited to, an optical isolator, a focusing lens, an optical fiber array, or an arrayed waveguide grating. FIGS. 3 to 5 exemplarily illustrate the optical module 200 as a receiver optical subassembly, which may include a photodiode as the optical communication unit 230, a transimpedance amplifier as the electronic component 240, and an optical fiber array as the optical transferring unit 260. FIGS. 3 to 5 exemplarily illustrate the optical communication unit 230 as a photodiode and the electronic component 240 as a transimpedance amplifier.

The heat dissipation component 250 may be in thermal contact with the electronic component 240. Further, the electronic component 240 may be understood as a heat source inside the optical module 200. The electronic component 240 may have a mounting surface 241 and a heat dissipation surface 242 opposite to each other. The mounting surface 241 faces toward the substrate 220, and the heat dissipation component 250 is in contact with the heat dissipation surface 242. The heat dissipation component 250 may be in direct or indirect contact with the heat dissipation surface 242. Specifically, the heat dissipation component 250 may be adhered to the heat dissipation surface 242 by a thermal conductive paste TCG (such as a silver paste), thereby realizing the indirect contact between the heat dissipation component 250 and the electronic component 240.

According to one embodiment of the present disclosure, the heat dissipation component 250 may include a heat dissipation body 251 and a thermally conductive medium 252. As shown in FIGS. 4 and 5, the heat dissipation body 251 may be located between the electronic component 240 and the thermally conductive medium 252. The heat dissipation body 251 may be in thermal contact with the electronic component 240, and the heat dissipation body 251 may be in contact with the heat dissipation surface 242 of the electronic component 240. Specifically, the heat dissipation body 251 may be adhered to the heat dissipation surface 242 by the thermal conductive adhesive TCG.

According to one embodiment of the present disclosure, the electronic component 240 may have a flip chip structure. Further, the mounting surface 241 of the electronic component 240 may have an electrical interconnect electrically connected to the substrate 220, or an electrical interconnect disposed adjacent to an edge of the mounting surface 241. The said electrical interconnect may be understood as a metal protrusion, a metal pad, or a pin. The heat dissipation surface 242 of the electronic component 240 may not have electrical interconnect. Alternatively, the heat dissipation surface 242 may have an electrical interconnect, and the area of the heat dissipation surface 242 is large enough to prevent a heat dissipation body 251 of the heat dissipation component 250 from being in contact with the electrical interconnect located on the heat dissipation surface 242. Therefore, the heat generated by the heat source may be transferred to the heat dissipation component 250 in contact with the heat source without being transferred to the copper pour inside the substrate 220, thereby improving the heat dissipation efficiency.

According to one embodiment of the present disclosure, the thermally conductive medium 252 of the heat dissipation component 250 may include a liquid heat conducting constituent or a liquable heat conducting constituent. The liquid heat conducting constituent or liquable heat conducting constituent may be provided to improve thermal dissipation capability of the heat dissipation component 250. In one embodiment, the thermally conductive medium 252 may be a sintered ceramic sheet impregnated with silicone oil, where the silicone oil may be understood as a liquid heat conducting constituent. Here, the term “liquid heat conducting constituent” may refer to a liquid or a gel with high thermal conductivity, which is coated on an outer surface of the thermally conductive medium 252 or distributed in pores of the thermally conductive medium 252 through capillary phenomenon. The term “liquable heat conducting constituent” may refer to a solid substance that is capable of undergoing a phase change into a liquid with high thermal conductivity at high temperature, or refer to any substance that is capable of reacting with the surrounding medium (such as air or liquid coolant) to form a liquid with high thermal conductivity at high temperature.

The term “thermally conductive medium” used herein may refer to all portions of a thermally conductive medium as depicted in FIG. 4, or at least one portion of a thermally conductive medium containing the liquid heat conducting constituent or liquable heat conducting constituent. In one embodiment, a thermally conductive medium may include a first portion containing the liquid heat conducting constituent or liquable heat conducting constituent, as well as a second portion without said constituent, and the first portion thereof may be understood as said thermally conductive medium of the present disclosure.

According to one embodiment of the present disclosure, the optical module 200 may further include a protective cover 270 disposed on the substrate 220. As shown in FIGS. 3 and 4, a top portion of the protective cover 270 may have an opening OP. The heat dissipation body 251 of the heat dissipation component 250 may extend through the opening OP, and an entirety of the thermally conductive medium 252 and the electronic component 240 may be located on opposite sides of the top portion, respectively.

According to one embodiment of the present disclosure, the heat dissipation body 251 of the heat dissipation component 250 may have a flange 251a. As shown in FIGS. 4 and 5, the heat dissipation body 251 may include a central portion 251b in contact with the heat dissipation surface 242 of the electronic component 240 and a flange 251a protruding from the central portion 251b. Further, the central portion 251b may axially extend through the opening OP, and the flange 251a may protrude radially. The flange 251a may be closer to the electronic component 240 and the substrate 220 than the top portion of the protective cover 270, and a portion of the flange 251a may be located between the top portion of the protective cover 270 and the substrate 220.

According to one embodiment of the present disclosure, a maximum width MW of the heat dissipation body 251 may be larger than an aperture AP of the opening OP. As shown in FIGS. 4 and 5, the flange 251a of the heat dissipation body 251 may define the maximum width MW of the heat dissipation body 251, and the maximum width MW may be larger than the aperture AP of the opening OP. Further, a width of the gap between the heat dissipation body 251 and the opening OP may be smaller than a radial dimension of the flange 251a.

The protective cover 270 and the flange 251a of the heat dissipation component 250 prevent the heat conducting constituent of the thermally conductive medium 252 from flowing to the electronic component 240 or the substrate 220. As shown in FIG. 5, the liquid heat conducting constituent may flow toward the protective cover 270 from the thermally conductive medium along a flowing direction FD. The protective cover 270 is able to block the liquid heat conducting constituent, such that the heat conducting constituent may be accumulated above the protective cover 270. In order to facilitate the assembly, there may be a gap between the heat dissipation body 251 and the opening OP, and the liquid heat conducting constituent may flow under the protective cover 270 via the gap. In this case, the flange 251a is able to allow the liquid heat conducting constituent flowing under the protective cover 270 to be accumulated in a space between the flange 251a and the protective cover 270, thereby preventing the liquid heat conducting constituent from contaminating the internal environment of the optical module 200.

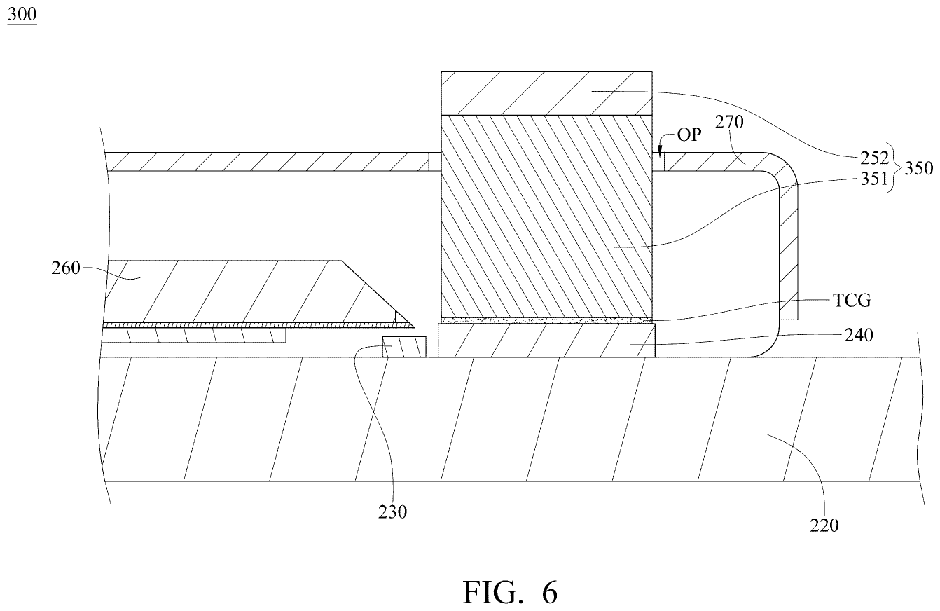

FIGS. 3 to 5 exemplarily illustrate the heat dissipation body 251 including the flange 251a, but the present disclosure is not limited thereto. FIG. 6 is a side view of components of an optical module 300 according to another embodiment of the present disclosure. In this embodiment, a heat dissipation body 351 of a heat dissipation component 350 does not include a flange, but blocks the liquid heat conducting constituent by a protective cover 270. In this case, in order to prevent the liquid heat conducting constituent from flowing under the protective cover 270, the size of the opening OP and a width of the heat dissipation body 351 may be designed to be nearly the same.

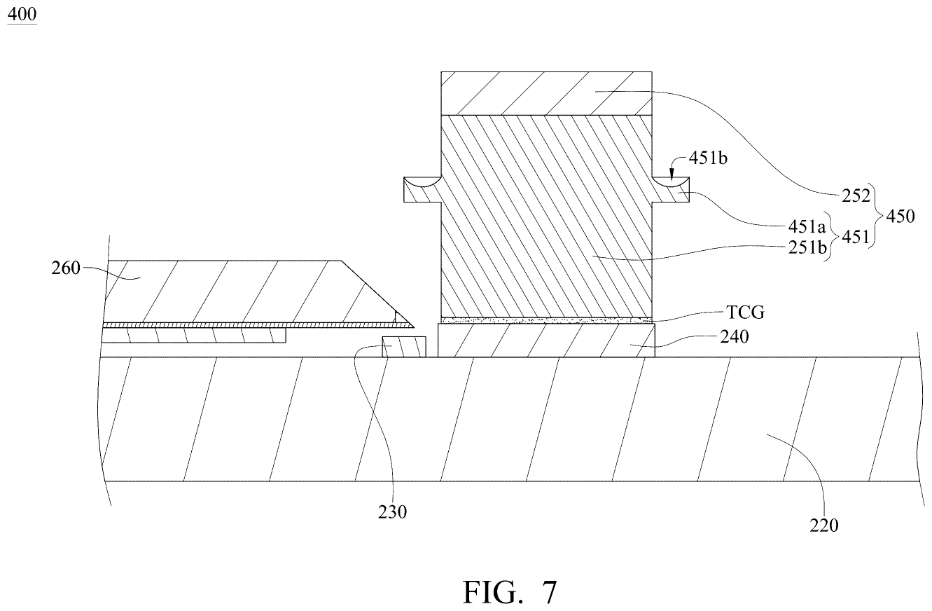

FIGS. 3 to 5 exemplarily illustrate the heat dissipation component 250 including the protective cover 270, but the present disclosure is not limited thereto. FIG. 7 is a side view of components of an optical module 400 according to still another embodiment of the present disclosure. In this embodiment, the optical module 400 does not include the protective cover, but blocks the liquid heat conducting constituent by a flange 451a of a heat dissipation body 451 of a heat dissipation component 450. In this case, a surface of the flange 451a may have a recess 451b or a concave shape to accommodate more liquid heat conducting constituent.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An optical module, comprising:
a substrate;
an electronic component, disposed on the substrate; and
a heat dissipation component, in thermal contact with the electronic component;
wherein, the heat dissipation component comprises a heat dissipation body and a thermally conductive medium, the heat dissipation body is located between the electronic component and the thermally conductive medium, the electronic component has a mounting surface and a heat dissipation surface opposite to each other, the mounting surface faces toward the substrate, and the heat dissipation body is in contact with the heat dissipation surface.

2. The optical module according to claim 1, wherein the thermally conductive medium comprises a liquid heat conducting constituent or a liquable heat conducting constituent.

3. The optical module according to claim 1, wherein the heat dissipation body comprises a central portion in contact with the heat dissipation surface and a flange protruding from the central portion.

4. The optical module according to claim 1, wherein the heat dissipation body is adhered to the heat dissipation surface of the electronic component through a thermal conductive adhesive.

5. The optical module according to claim 1, further comprising a protective cover disposed on the substrate, wherein the protective cover has an opening, the heat dissipation body extends through the opening, and an entirety of the thermally conductive medium and the electronic component are located on opposite sides of the protective cover, respectively.

6. The optical module according to claim 5, wherein a maximum width of the heat dissipation body is larger than an aperture of the opening.

7. The optical module according to claim 5, wherein the heat dissipation body comprises a central portion in contact with the heat dissipation surface and a flange protruding from the central portion, and a portion of the flange is located between the protective cover and the substrate.

8. The optical module according to claim 1, further comprising an optical communication unit disposed on the substrate, wherein the electronic component is electrically connected to the optical communication unit.

9. The optical module according to claim 1, wherein the electronic component has a flip chip structure.

10. A receiver optical subassembly, comprising:
a photodiode;
a substrate;
a transimpedance amplifier, disposed on the substrate, wherein the transimpedance amplifier is electrically connected to the photodiode; and
a heat dissipation component, in thermal contact with the transimpedance amplifier;
wherein, the transimpedance amplifier has a flip chip structure, the transimpedance amplifier has a mounting surface and a heat dissipation surface opposite to each other, the mounting surface faces toward the substrate, and the heat dissipation component is in contact with the heat dissipation surface.

11. The receiver optical subassembly according to claim 10, wherein the heat dissipation component comprises a heat dissipation body and a thermally conductive medium, the heat dissipation body is located between the transimpedance amplifier and the thermally conductive medium, and the heat dissipation body is in contact with the heat dissipation surface.

12. The receiver optical subassembly according to claim 11, wherein the thermally conductive medium comprises a liquid heat conducting constituent or a liquable heat conducting constituent.

13. The receiver optical subassembly according to claim 11, wherein the heat dissipation body comprises a central portion in contact with the heat dissipation surface and a flange protruding from the central portion.

14. The receiver optical subassembly according to claim 11, further comprising a protective cover, wherein the protective cover has an opening, the heat dissipation body extends through the opening, and an entirety of the thermally conductive medium and the transimpedance amplifier are located on opposite sides of the protective cover, respectively.

15. The receiver optical subassembly according to claim 14, wherein a maximum width of the heat dissipation body is larger than an aperture of the opening.

16. An optical module, comprising:
an optical communication unit;
an electronic component, electrically connected to the optical communication unit;
a heat dissipation component, comprising a heat dissipation body and a thermally conductive medium, wherein the heat dissipation body is located between the electronic component and the thermally conductive medium, and the heat dissipation body is in thermal contact with the electronic component; and
a protective cover, having an opening, wherein the heat dissipation body extends through the opening, and an entirety of the thermally conductive medium and the electronic component are located on opposite sides of the protective cover, respectively.

17. The optical module according to claim 16, wherein the thermally conductive medium comprises a liquid heat conducting constituent or a liquable heat conducting constituent.

18. The optical module according to claim 16, wherein the heat dissipation body comprises a central portion in contact with the electronic component and a flange protruding from the central portion, and the entirety of the thermally conductive medium and the flange are located on opposite sides of the protective cover, respectively.

19. The optical module according to claim 16, wherein a maximum width of the heat dissipation body is larger than an aperture of the opening.

20. The optical module according to claim 16, wherein the electronic component has a flip chip structure.
